(19) United States
(12) Patent Application Publication
(10) Pub. No.: US 2024/0332476 A1
(43) Pub. Date: Oct. 3, 2024

(54) MICRO-DISPLAY LED CHIP STRUCTURE AND MANUFACTURING METHOD FOR THE SAME

(71) Applicant: RAYSOLVE OPTOELECTRONICS (SUZHOU) CO., LTD., Suzhou (CN)

(72) Inventor: Wing Cheung CHONG, Suzhou (CN)

(73) Assignee: RAYSOLVE OPTOELECTRONICS (SUZHOU) CO., LTD., Suzhou (CN)

(21) Appl. No.: 18/736,242

(22) Filed: Jun. 6, 2024

Related U.S. Application Data
(63) Continuation of application No. PCT/CN2022/126449, filed on Oct. 20, 2022.

(30) Foreign Application Priority Data
Dec. 8, 2021 (CN) 202111489530.3

(51) Int. Cl. H01L 33/62; H01L 27/15; H01L 33/00; H01L 33/36; H01L 33/52

(52) U.S. Cl. CPC H01L 33/62; H01L 27/156; H01L 33/0095; H01L 33/36; H01L 33/52; H01L 2933/0016; H01L 2933/005

(57) ABSTRACT

A micro-display LED chip structure includes: a first substrate; and an LED semiconductor layer disposed on the first substrate. The LED semiconductor layer includes a plurality of LED units arranged in an array, and adjacent LED units are capable of being driven independently. The first substrate includes a driving circuit, the driving circuit is provided with a plurality of contacts, each contact of the plurality of contacts corresponds to an LED unit, the contact is located in an orthographic projection region, on the first substrate, of the LED unit corresponding to the contact, and the contact is electrically connected to the LED unit. The micro-display LED chip structure according to embodiments of the present disclosure may reduce a distance between two adjacent LED units, and improve an area of a light-emitting region of the LED unit, thereby improving a light-emitting brightness of the micro-display LED chip structure.

### CROSS-REFERENCE TO RELATED APPLICATIONS

The present application is a continuation application of International Application No. PCT/CN2022/126449, filed on Oct. 20, 2022, which claims priority to Chinese Patent Application No. 202111489530.3, filed on Dec. 8, 2021. Both applications are incorporated herein by reference in their entireties.

### TECHNICAL FIELD

The present disclosure relates to a micro-display LED chip structure and a manufacturing method for the same, and relates to the field of micro-display technologies.

### BACKGROUND

A display having micro-sized Light-Emitting Diodes (LEDs) is referred to as micro-LEDs. A micro-LED display has a micro-LED array that forms single pixel elements. A pixel may be a tiny illumination region on a display screen, and an image may include a plurality of pixels. In other words, the pixels may be small discrete elements that together constitute an image on a display. The pixels are typically arranged in a two-dimensional (2D) matrix and are represented using dots, squares, rectangles, or other shapes. A pixel may be a base unit of a display or digital image and has geometric coordinates.

A display device in the field of micro display is mostly used to generate a high-brightness miniature display image, which is projected by an optical system to be perceived by an observer. A projection target may be a retina (virtual image) or a projection curtain (reality), which may be applied to various aspects such as Augmented Reality (AR), Virtual Reality (VR), automobile Head-Up Display (HUD).

A Micro-LED chip structure in a related art has a problem of a small area of a light-emitting region.

### SUMMARY

A main objective of the present disclosure is to provide a micro-display LED chip structure and a manufacturing method for the same to overcome disadvantages in the related art.

In order to achieve the above objective, technical solutions adopted by the present disclosure include the following contents.

Embodiments of the present disclosure provides a micro-display LED chip structure, which includes:
a first substrate; and
an LED semiconductor layer disposed on the first substrate, where the LED semiconductor layer includes a plurality of LED units arranged in an array, and adjacent LED units of the plurality of LED units are capable of being driven independently.

The first substrate includes a driving circuit, the driving circuit is provided with a plurality of contacts, each contact of the plurality of contacts corresponds to an LED unit in the plurality of LED units, the contact is located in an orthographic projection region, on the first substrate, of the LED unit corresponding to the contact, and the contact is electrically connected to the LED unit corresponding to the contact.

In a specific embodiment, the contact is located in a central region of the orthographic projection region, on the first substrate, of the LED unit corresponding to the contact.

In a specific embodiment, the LED semiconductor layer includes a first doping type semiconductor layer, an active layer and a second doping type semiconductor layer which are sequentially stacked on the first substrate, a through hole corresponding to a position of the contact is provided on the LED semiconductor layer, and the through hole penetrates through the LED semiconductor layer.

The micro-display LED chip structure further includes: a passivation layer disposed on the second doping type semiconductor layer, where the passivation layer further covers a sidewall of the through hole, the passivation layer is provided with a first opening and a second opening, the first opening exposes the contact, and the second opening exposes the second doping type semiconductor layer; and
an electrode layer disposed on the passivation layer and covering the first opening and the second opening, where the electrode layer is electrically connected to the contact through the first opening, and is electrically connected to the second doping type semiconductor layer through the second opening.

In a specific embodiment, the LED unit is provided with a step structure, and the adjacent LED units are electrically isolated by the step structure to enable the adjacent LED units to be driven independently.

In a specific embodiment, the step structure is formed on the second doping type semiconductor layer, a height of the step structure is greater than or equal to a thickness of the second doping type semiconductor layer and less than a thickness of the LED semiconductor layer, and the step structure at least electrically isolates second doping type semiconductor layers corresponding to the adjacent LED units.

In a specific embodiment, the step structure is formed on the second doping type semiconductor layer, a height of the step structure is equal to a thickness of the LED semiconductor layer, and the step structure electrically isolates active layers corresponding to the adjacent LED units, and electrically isolates first doping type semiconductor layers corresponding to the adjacent LED units.

In a specific embodiment, an isolation material layer is provided between the adjacent LED units, and the adjacent LED units are electrically isolated by the isolation material layer to enable the adjacent LED units to be driven independently.

In a specific embodiment, the isolation material layer is formed in the second doping type semiconductor layer, a thickness of the isolation material layer is greater than or equal to a thickness of the second doping type semiconductor layer, and the isolation material layer at least electrically isolates second doping type semiconductor layers corresponding to the adjacent LED units.

In a specific embodiment, a material of the isolation material layer includes an ion implantation material, and the ion implantation material includes any one or a combination of at least two of hydrogen, helium, nitrogen, oxygen, fluorine, magnesium, silicon, and argon, but is not limited thereto.

In a specific embodiment, first doping type semiconductor layers corresponding to the plurality of LED units are a common first doping type semiconductor layer.

In a specific embodiment, one of the first doping type semiconductor layer and the second doping type semiconductor layer is a P-type semiconductor layer, and the other of the first doping type semiconductor layer and the second doping type semiconductor layer is an N-type semiconductor layer.

In a specific embodiment, a bonding layer is disposed between the first substrate and the first doping type semiconductor layer.

In a specific embodiment, the bonding layer is provided with an etched hole at a position corresponding to the contact and the first opening, and the electrode layer electrically connects the second doping type semiconductor layer to the contact through the first opening and the etched hole.

Embodiments of the present disclosure provides a manufacturing method for a micro-display LED chip structure, which includes:
forming an LED semiconductor layer on a second substrate, where the LED semiconductor layer includes a second doping type semiconductor layer, an active layer and a first doping type semiconductor layer which are sequentially stacked on the second substrate;
bonding the first doping type semiconductor layer to a first substrate, and removing the second substrate to expose the second doping type semiconductor layer, where the first substrate includes a driving circuit, and the driving circuit is provided with a plurality of contacts; and
processing the LED semiconductor layer to form a plurality of LED units arranged in an array and enabling adjacent LED units of the plurality of LED units to be driven independently, where each contact of the plurality of contacts corresponds to an LED unit in the plurality of LED units, the contact is located in an orthographic projection region, on the first substrate, of the LED unit corresponding to the contact, and the contact is electrically connected to the LED unit corresponding to the contact.

In a specific embodiment, the processing the LED semiconductor layer to form a plurality of LED units arranged in an array includes: forming a plurality of step structures on the LED semiconductor layer through an etching process, where the plurality of step structures divide the LED semiconductor layer into the plurality of LED units arranged in an array.

In a specific embodiment, the forming a plurality of step structures on the LED semiconductor layer through an etching process includes:
removing a second doping type semiconductor layer located in a plurality of selected regions by etching, so as to form the plurality of step structures, where a height of each step structure of the plurality of step structures is greater than or equal to a thickness of the second doping type semiconductor layer and less than a thickness of the LED semiconductor layer, and the step structure at least isolates second doping type semiconductor layers corresponding to the adjacent LED units from each other.

In a specific embodiment, the forming a plurality of step structures on the LED semiconductor layer through an etching process includes:
removing a second doping type semiconductor layer, an active layer and a first doping type semiconductor layer which are located in a plurality of selected regions by etching, so as to form the plurality of step structures, where a height of each step structure of the plurality of step structures is equal to a thickness of the LED semiconductor layer, and the step structure isolates second doping type semiconductor layers, active layers and first doping type semiconductor layers corresponding to the adjacent LED units from each other, respectively.

In a specific embodiment, the processing the LED semiconductor layer to form a plurality of LED units arranged in an array includes:
forming an isolation material layer in the second doping type semiconductor layer by ion implantation, and controlling an implantation depth of an ion implantation material to enable a thickness of the isolation material layer to be greater than or equal to a thickness of the second doping type semiconductor layer, where the isolation material layer at least electrically isolates the second doping type semiconductor layers corresponding to the adjacent LED units, and divides the LED semiconductor layer into the plurality of LED units arranged in an array.

In a specific embodiment, the processing the LED semiconductor layer to form a plurality of LED units arranged in an array and enabling adjacent LED units of the plurality of LED units to be driven independently includes:
forming a through hole penetrating through the LED semiconductor layer at a position, corresponding to the contact, on the second doping type semiconductor layer, where a bottom of the through hole exposes the contact;
forming a passivation layer on the second doping type semiconductor layer, where the passivation layer covers a sidewall of the through hole;
forming a first opening and a second opening on the passivation layer, where the first opening exposes the contact, and the second opening exposes the second doping type semiconductor layer; and
forming an electrode layer on the passivation layer, where the electrode layer is electrically connected to the contact through the first opening, and is electrically connected to the second doping type semiconductor layer through the second opening.

In a specific embodiment, the bonding the first doping type semiconductor layer to a first substrate includes: forming a bonding layer on the first doping type semiconductor layer and/or the first substrate, and then bonding the first doping type semiconductor layer to the first substrate through the bonding layer.

The contacts on the first substrate in the micro-display LED chip structure according to the embodiments of the present disclosure are correspondingly disposed in a region directly below each LED unit, rather than disposed between the adjacent LED units, so that a distance between two adjacent LED units may be reduced, and an area of a light-emitting region of the LED unit is increased, thereby improving a light-emitting brightness of the micro-display LED chip structure.

### BRIEF DESCRIPTION OF THE DRAWINGS

FIG. 1a is a top view of a micro-display LED chip structure according to an embodiment of the present disclosure.

FIG. 1b is a top view of a micro-display LED chip structure according to another embodiment of the present disclosure.

FIG. 2a is a cross-sectional view of an illustrative micro-display LED chip structure along the line A-A′ or B-B′ in FIG. la.

FIG. 2b is a cross-sectional view of a micro-display LED chip structure according to another embodiment of the present disclosure.

FIG. 3a to FIG. 3i are schematic structural diagrams of a plurality of intermediate structures in a manufacturing process of a micro-display LED chip structure according to an embodiment of the present disclosure.

FIG. 4a to FIG. 4e are schematic structural diagrams of a plurality of intermediate structures in a partial manufacturing process of a micro-display LED chip structure according to another embodiment of the present disclosure.

### DETAILED DESCRIPTION OF THE EMBODIMENTS

In view of deficiencies in the related art, the applicant of the present disclosure has provided the technical solutions of the present disclosure through long-term research and extensive practices. The technical solution, implementation processes and principles of the technical solutions, and the like may be further explained as follows.

The term “layer” used in the embodiments of the present disclosure refers to a material portion including a region having a certain thickness. The layer may extend over an entire lower layer or upper layer structure, or may have a coverage area that is less than the lower layer or upper layer structure. In addition, the layer may be a region of a homogeneous or heterogeneous continuous structure, which has a thickness less than a thickness of the continuous structure. For example, the layer may be located between a top surface and a bottom surface of the continuous structure or between any pair of horizontal planes between a top surface and a bottom surface of the continuous structure. The layer may extend horizontally, vertically, and/or along a tapered surface. A second substrate may be a layer, may include one or more layers therein, and/or may have one or more layers on, above, and/or below it. A layer may include multiple layers. For example, a semiconductor layer may include one or more doped or undoped semiconductor layers, and may have the same or different materials.

As used in the embodiments of the present disclosure, “micro” in terms “micro” LED, “micro” P-N diode, or “micro” device refers to a descriptive size of specific devices or structures according to embodiments of the present disclosure. The term “micro” device or structure used in the embodiments of the present disclosure is intended to represent a device or structure with a scale of 0.1 to 100 μm. However, it should be understood that the embodiments of the present disclosure are not necessarily limited to this, and specific aspects of the embodiments may be applicable to larger and possibly smaller size-scale devices or structures.

The term “second substrate” as used in the embodiments of the present disclosure refers to a material on which a subsequent material layer is added, the second substrate itself may be patterned, and the material added to a top of the second substrate may be patterned or may remain unpatterned. In addition, the second substrate may include a wide variety of semiconductor materials, such as silicon, silicon carbide, gallium nitride, germanium, gallium arsenide, or indium phosphide. Alternatively, the second substrate may be made of a non-conductive material, such as glass, plastic, or sapphire wafer. The first substrate has a semiconductor device or a driving circuit formed therein, and the driving circuit or the semiconductor device may be formed by processing according to specific requirements, which is not specifically limited herein.

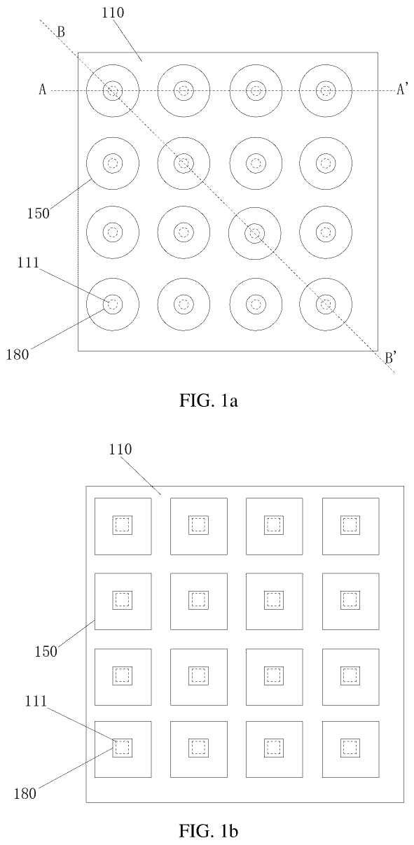

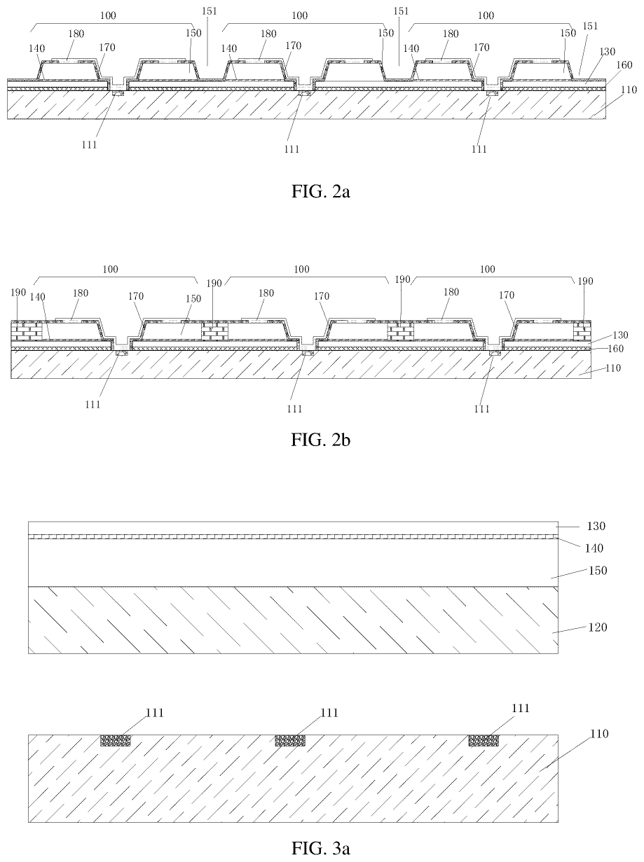

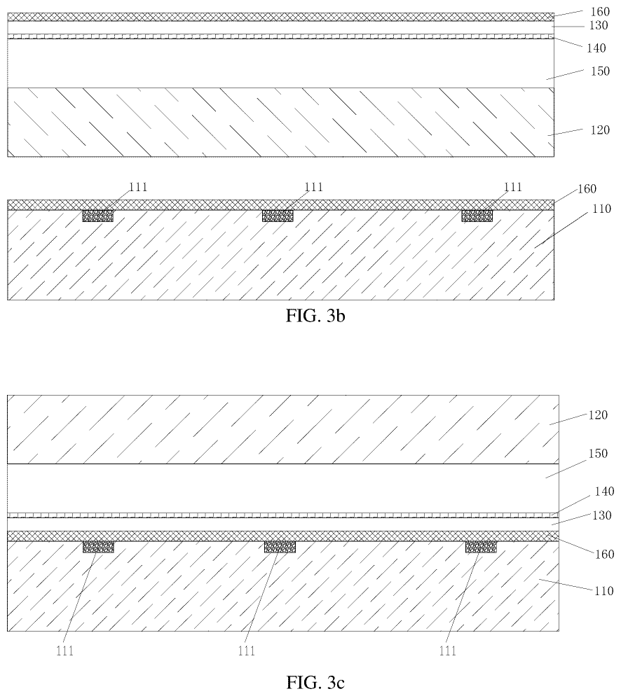

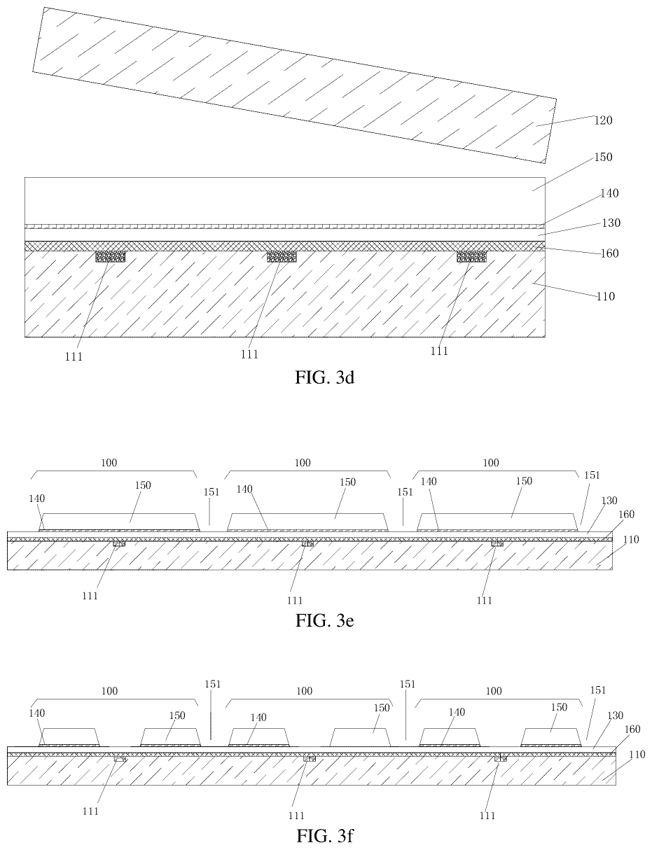

FIG. 1a and FIG. 1b illustrate top views of illustrative micro-display LED chip structures according to some embodiments of the present disclosure, and FIG. 2a illustrates a cross-sectional view of an illustrative micro-display LED chip structure along the line A-A′ or B-B′ in FIG. 1a.

Referring to FIGS. 1a and 2a, a micro-display LED chip structure includes a first substrate 110 and an LED semiconductor layer formed on the first substrate 110. The LED semiconductor layer may be fixedly bonded to the first substrate 110 through a bonding layer 160, and the LED semiconductor layer includes a plurality of LED units arranged in an array.

In an embodiment, an LED unit 100 of the plurality of LED units is provided with a step structure 151, and the step structure 151 electrically isolates two adjacent LED units 100, so that each LED unit 100 can be driven independently. The first substrate 110 includes a driving circuit, the driving circuit has a plurality of contacts 111, each contact 111 corresponds to an LED unit 100, each contact 111 is located in an orthographic projection region, on the first substrate 110, of the LED unit 100 corresponding to the contact 111, and the LED unit 100 is further electrically connected to the contact 111 on the first substrate 110 through an electrode layer 180.

Taking one of the LED units 100 as an example, the LED semiconductor layer includes a first doping type semiconductor layer 130, an active layer 140, and a second doping type semiconductor layer 150 that are sequentially stacked on the first substrate 110. A through hole corresponding to a position of the contact 111 is provided on the LED semiconductor layer, and the through hole penetrates through the LED semiconductor layer.

In an embodiment, the through hole may be disposed in a central region of the LED semiconductor layer, and penetrates through the first doping type semiconductor layer 130, the active layer 140, the second doping type semiconductor layer 150, and the bonding layer 160 along a thickness direction.

In an embodiment, the first substrate 110 may be made of a semiconductor material such as silicon, silicon carbide, gallium nitride, germanium, gallium arsenide, indium phosphide, and of course, the first substrate 110 may also be made of a non-conductive material such as glass, plastic, or sapphire wafer. In an embodiment, the first substrate 110 includes a driving circuit, and the first substrate 110 may be a Complementary Metal Oxide Semiconductor (CMOS) backplane, a Thin Film Transistor (TFT) glass substrate, or the like. The driving circuit is configured to provide an electrical signal to the LED unit 100 to control brightness.

In an embodiment, the driving circuit may include an active matrix driving circuit, and each individual LED unit 100 is equivalent to an independent driver. Optionally, in an embodiment, the driving circuit may include a passive matrix driving circuit, and the plurality of LED units 100 are distributed in an array and connected to a data line and a scan line that are driven by the driving circuit.

In an embodiment, the bonding layer 160 is further provided with an etched hole exposing the contact 111 at a position corresponding to the contact 111, and the bonding layer 160 may be an adhesion material layer formed on the first substrate 110 to bond the first substrate 110 and the LED semiconductor layer. In an embodiment, a material of the bonding layer 160 may be a conductive material, such as a metal or a metal alloy, for example, the material of the bonding layer 160 may be Au, Sn, In, Cu, Ti, or the like, and which is not limited thereto.

In an embodiment, the material of the bonding layer 160 may also be a non-conductive material, such as polyimide (PI), or polydimethylsiloxane (PDMS), and which is not limited thereto.

In an embodiment, the material of the bonding layer 160 may also be a photoresist and the like, such as a SU-8 photoresist, and which is not limited thereto.

In an embodiment, the material of the bonding layer 160 may also be hydrogen silsesquioxane (HSQ), divinyl siloxane-bis-benzocyclobutene (DVS-BCB), or the like, and which is not limited thereto.

It should be understood that the description of the material of the bonding layer 160 is merely exemplary, rather than limiting, a person skilled in the art may make changes according to requirements, and all these changes are within the scope of the present disclosure.

In an embodiment, the first doping type semiconductor layer 130, the active layer 140, and the second doping type semiconductor layer 150 are sequentially stacked on the bonding layer 160, the bonding layer 160 is disposed on the first substrate 110, and the LED semiconductor layer is electrically connected to the contact 111 located on the first substrate 110 through the electrode layer 180.

In an embodiment, the active layer 140 is disposed between the first doping type semiconductor layer 130 and the second doping type semiconductor layer 150 and is configured to provide light, the active layer 140 is a layer that recombines holes and electrons respectively provided from the first doping type semiconductor layer 130 and the second doping type semiconductor layer 150 and outputs light of a specific wavelength, and the active layer 140 may have a single-quantum-well structure, or a Multi-Quantum-Well (MQW) structure in which a well layer and a barrier layer are stacked alternately.

In an embodiment, a step structure 151 is formed on the second doping type semiconductor layer 150, a height of the step structure 151 is greater than or equal to a thickness of the second doping type semiconductor layer 150 and less than or equal to a thickness of the LED semiconductor layer, and the step structure 151 at least isolates the second doping type semiconductor layers 150 of the adjacent LED units from each other, that is, the step structure 151 penetrates through and divides the second doping type semiconductor layer 150 along the thickness direction.

In an embodiment, a material of the first doping type semiconductor layer 130 and a material of the second doping type semiconductor layer 150 may be one or more layers formed by a II-VI material (such as ZnSe or ZnO) or a III-V nitride material (such as GaN, AIN, InN, InGaN, GaP, AlInGaP, AlGaAs, and alloys thereof).

In an embodiment, a thickness of the first doping type semiconductor layer 130 is 0.05 μm to 1 μm, preferably 0.05 μm to 0.7 μm, and particularly preferably 0.05μm to 0.5 μm.

In an embodiment, the first doping type semiconductor layer 130 may be P-type GaN. In an embodiment, the first doping type semiconductor layer 130 may be formed by doping magnesium (Mg) in GaN. In some other embodiments, the first doping type semiconductor layer 130 may also be P-type InGaN, P-type AlInGaP or the like.

In an embodiment, each LED unit 100 has an anode and a cathode connected to the driving circuit, for example, the driving circuit is formed in the first substrate 110 (the driving circuit is not explicitly shown). For example, each LED unit 100 has an anode connected to a constant voltage source and has a cathode connected to a source/drain of the driving circuit.

In an embodiment, the second doping type semiconductor layer 150 may be an N-type semiconductor layer and forms a cathode of the LED unit 100.

In an embodiment, the second doping type semiconductor layer 150 may be N-type GaN, N-type InGaN, N-type AlInGaP, or the like.

In an embodiment, the second doping type semiconductor layers 150 of different LED units 100 are electrically isolated, so that each LED unit 100 may have a cathode with a different voltage level than other LED units. As a result of the disclosed embodiments, a plurality of LED units 100 that may operate individually are formed, the first doping type semiconductor layer 130 extends horizontally across the adjacent LED units, and the second doping type semiconductor layer 150 is electrically isolated between the adjacent LED units.

In an embodiment, the active layer (that is, a MQW layer) 140 is an active region of the LED semiconductor layer. In an embodiment, a thickness of the LED semiconductor layer (the first doping type semiconductor layer 130, the active layer 140, and the second doping type semiconductor layer 150) is 0.4 μm to 4 μm, and preferably 0.5 μm to 3 μm.

It should be noted that the first doping type semiconductor layer 130 may also be an N-type semiconductor layer, and correspondingly, when the first doping type semiconductor layer 130 is an N-type semiconductor layer, the second doping type semiconductor layer 150 is a P-type semiconductor layer.

In an embodiment, the step structure 151 is formed on the second doping type semiconductor layer 150, that is, the step structure penetrates through and divides the second doping type semiconductor layer 150 along a thickness direction. A step surface of the step structure serves as a light-emitting region of the LED semiconductor layer. The step surface herein may refer to an upper surface of the second doping type semiconductor layer 150 in one LED unit.

In an embodiment, the LED semiconductor layer is provided with the through hole, the contact 111 on the first substrate 110 is exposed through the through hole, and the through hole penetrates through the second doping type semiconductor layer 150, the active layer 140 and the first doping type semiconductor layer 130 from a surface of the second doping type semiconductor layer 150 along a thickness direction. The through hole is located in a central region of the LED semiconductor layer, and it can be understood that an orthographic projection region, on the first substrate, of the through hole is located in a region of an orthographic projection region, on the first substrate, of the LED semiconductor layer, and is further located in a central region of the orthographic projection region, on the first substrate, of the LED semiconductor layer. The central region refers to a geometric center of the orthographic projection region of the LED semiconductor layer. Correspondingly, the contact 111 on the first substrate 110 is correspondingly disposed at a central position of the orthographic projection region, on the first substrate 100, of each LED unit or the LED semiconductor layer.

In an embodiment, a passivation layer 170 is at least formed on the second doping type semiconductor layer 150, an exposed portion of the first doping type semiconductor layer 130 and an exposed portion of the active layer 140, and the passivation layer 170 may be configured to protect and isolate the LED unit 100.

In an embodiment, the passivation layer 170 is disposed on the second doping type semiconductor layer 150, and the passivation layer 170 further covers a sidewall of the through hole.

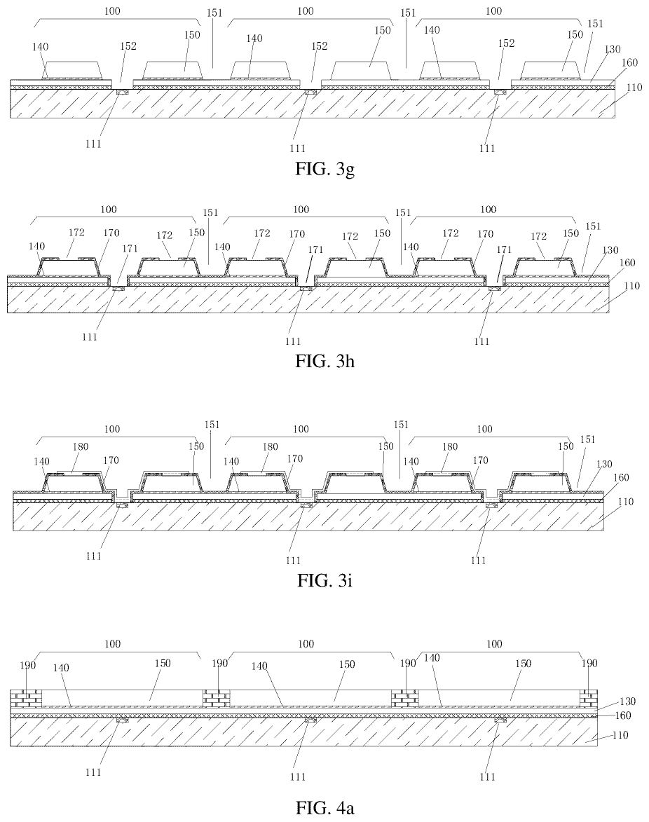

In an embodiment, a material of the passivation layer 170 may be SiO₂, Al₂O₃, SiN, other suitable materials, or the like. In an embodiment, the material of the passivation layer 170 may also be polyimide, SU-8 photoresist, other photo-patternable polymers, or the like. The electrode layer 180 is formed on a portion of the passivation layer 170, and referring to FIG. 3h, the passivation layer 170 is provided with a first opening 171 and a second opening 172. The through hole is correspondingly disposed at the first opening 171, the first opening 171 exposes the contact. The electrode layer 180 is electrically connected to the contact 111 through the first opening 171 on the passivation layer 170 and the through hole, and the electrode layer 180 is electrically connected to the second doping type semiconductor layer 150 through the second opening 172 on the passivation layer 170.

In an embodiment, the first opening 171 is preferably disposed in a central region of each LED unit 100, and a shape of the first opening 171 may be circular, square or the like. Of course, the first opening 171 may have another regular or irregular pattern. The second opening 172 is disposed around the first opening 171, and a shape of the second opening 172 may be defined according to specific needs, which is not limited in this embodiment.

In an embodiment, a material of the electrode layer 180 may be a transparent conductive material, for example, the material of the electrode layer 180 includes a conductive metal oxide such as indium tin oxide (ITO) or zinc oxide (ZnO), or the material of the electrode layer 180 may be a conductive metal material such as Cr, Ti, Pt, Au, Al, Cu, Ge, or Ni.

In an embodiment, the first substrate 110 has the driving circuit formed therein and configured to drive the LED unit 100, the contact 111 of the driving circuit is located in a region directly below the LED unit 100, and the contact 111 is electrically connected to the second doping type semiconductor layer 150 through the electrode layer 180. It may be understood that an electrical connection between the second doping type semiconductor layer 150 and the contact 111 of the driving circuit is accomplished by the electrode layer 180.

In an embodiment, as described above, the second doping type semiconductor layer 150 forms the cathode of each LED unit 100, so that the contact 111 provides a driving voltage for the cathode of each LED unit 100 from the driving circuit to the second doping type semiconductor layer 150 through the electrode layer 180.

The contact on the first substrate in the micro-display LED chip structure according to the embodiments of the present disclosure is correspondingly disposed in a region directly below each LED unit 100, and the electrode layer is disposed in a central region of each LED unit 100 and is connected to a contact located in a region directly below the LED unit 100, so that a space between two adjacent LED units 100 may be reduced, and a light-emitting region of the LED unit 100 is improved, thereby improving a light-emitting brightness of the micro-display LED chip structure.

In addition, in the related art, a typical manufacturing process of a Micro-LED is: first forming a Micro-LED array, then transferring the Micro-LED array to a circuit substrate (for example, a TFT board, a COMS board or the like) in batches, and finally performing encapsulation. However, due to a small size and a high positioning accuracy requirement of the Micro-LED, how to transfer a Micro-LED chip to the circuit substrate in batches with high efficiency and high yield becomes a technical bottleneck that needs to be broken through urgently in applying the Micro-LED to the field of micro-display technologies. According to the technical solutions provided by the embodiments of the present disclosure, the space between two adjacent LED units 100 may be reduced, an integration level is further improved, and a size of the LED unit is increased to improve a brightness. Moreover, the LED array is directly formed on an LED epitaxial layer after bonding the LED epitaxial layer with a driving substrate, so that the yield may be improved to a certain extent without using a batch transfer technology in the related art.

FIGS. 3a to 3i illustrate cross-sectional views of a plurality of intermediate structures in a process of manufacturing a micro-display LED chip structure according to some embodiments of the present disclosure.

Referring to FIG. 3a to FIG. 3i, a manufacturing method for a micro-display LED chip structure according to an embodiment of the present disclosure may include the following steps.
1) Referring to FIG. 3a, sequentially forming a second doping type semiconductor layer 150, an active layer 140, and a first doping type semiconductor layer 130 on a second substrate 120, where the second doping type semiconductor layer 150, the active layer 140, and the first doping type semiconductor layer 130 form an LED semiconductor layer; and providing a first substrate 110, where the first substrate 110 includes a driving circuit, and the first substrate 110 is further provided with a plurality of contacts 111.

A material of the second substrate 120 may be a non-conductive material such as glass, plastic, or sapphire wafer, and the first substrate 110 may be made of a semiconductor material such as silicon, silicon carbide, gallium nitride, germanium, gallium arsenide, or indium phosphide. Of course, the first substrate 110 may also be made of a non-conductive material such as glass, plastic, or sapphire wafer. In an embodiment, the first substrate 110 may be a CMOS backplane, a TFT glass substrate, or the like, and the driving circuit is configured to provide an electrical signal to a LED unit 100 to control the brightness. In an embodiment, the driving circuit may include an active matrix driving circuit, and each individual LED unit 100 is equivalent to an independent driver. Optionally, in an embodiment, the driving circuit may include a passive matrix driving circuit, and a plurality of LED units 100 are distributed in an array and connected to a data line and a scan line that are driven by the driving circuit.

In some embodiments, the second doping type semiconductor layer 150, the active layer 140, and the first doping type semiconductor layer 130 may be formed by a process such as Chemical Vapor Deposition (CVD), Physical Vapor Deposition (PVD), Atomic Layer Deposition (ALD), Plasma Enhanced CVD (PECVD), or Plasma Enhanced ALD (PEALD). In an embodiment, materials of the first doping type semiconductor layer 130 and the second doping type semiconductor layer 150 may be II-VI materials (such as ZnSe or ZnO) or III-V nitride materials (such as GaN, AlN, InN, InGaN, GaP, AlInGaP, AlGaAs, and alloys thereof). The first doping type semiconductor layer 130 may be a P-type semiconductor layer as an anode. In an embodiment, a thickness of the first doping type semiconductor layer 130 is 0.05 μm to 1 μm, preferably 0.05 μm to 0.7 μm, and especially preferably 0.05 μm to 0.5 μm. In an embodiment, the first doping type semiconductor layer 130 may be formed by doping magnesium (Mg) in GaN. In some other embodiments, the first doping type semiconductor layer 130 may also be P-type InGaN, P-type AlInGaP or the like. In an embodiment, the second doping type semiconductor layer 150 may be an N-type semiconductor layer, and the second doping type semiconductor layer 150 serves as a cathode of each LED unit 100. In an embodiment, the second doping type semiconductor layer 150 may be N-type GaN, N-type InGaN, N-type AlInGaP, or the like. In an embodiment, the active layer (that is, a MQW layer) 140 is an active region of the LED semiconductor layer. In an embodiment, a thickness of the LED semiconductor layer (the first doping type semiconductor layer 130, the MQW layer 140, and the second doping type semiconductor layer 150) is 0.4 μm to 4 μm, and preferably 0.5 μm to 3 μm. Certainly, the first doping type semiconductor layer 130 may also be an N-type semiconductor layer, and correspondingly, when the first doping type semiconductor layer 130 is the N-type semiconductor layer, the second doping type semiconductor layer 150 is a P-type semiconductor layer.
2) Referring to FIGS. 3b and 3c, forming a bonding layer 160 on the first doping type semiconductor layer 130 and/or the first substrate 110, and bonding the first substrate 110 to the first doping type semiconductor layer 130 through the bonding layer 160.

The bonding layer 160 may be an adhesion material layer formed on the first substrate 110 to bond the first substrate 110 and the LED unit 100.

In an embodiment, a material of the bonding layer 160 may be a conductive material, such as a metal or a metal alloy, for example, the material of the bonding layer may be Au, Sn, In, Cu, Ti, or the like. In some other embodiments, the material of the bonding layer 160 may be a non-conductive material, such as polyimide (PI), or polydimethylsiloxane (PDMS). In an embodiment, the material of the bonding layer 160 may also be a photoresist and the like, such as a SU-8 photoresist. In some other embodiments, the material of the bonding layer 160 may also be hydrogen silsesquioxane (HSQ), divinyl siloxane-bis-benzocyclobutene (DVS-BCB), or the like. It should be understood that the description of the material of the bonding layer 160 is merely exemplary, rather than limiting, a person skilled in the art may make changes according to requirements, and all these changes are within the scope of the present disclosure.
3) Referring to FIG. 3d, removing the second substrate 120.

A method of removing the second substrate 120 may be direct stripping or other means known to those skilled in the art. Of course, after the second substrate 120 is removed, a thinning operation may be performed on the second doping type semiconductor layer 150 to remove a portion of the second doping type semiconductor layer 150. In some embodiments, the thinning operation may include a dry etching or a wet etching operation. In some embodiments, the thinning operation may include a Chemical Mechanical Polishing (CMP) operation, or the like.
4) Referring to FIG. 3e, removing the second doping type semiconductor layer 150 located in a predetermined region (a selected region) by etching or the like to form a step structure 151.

The step structure 151 divides the second doping type semiconductor layer 150 to form a plurality of LED step surfaces, each LED step surface corresponds to an LED unit, each LED unit is correspondingly disposed directly above a contact 111, and the contact 111 is located in a central region of the LED unit corresponding to the contact 111.

A height of the step structure 151 is greater than or equal to a thickness of the second doping type semiconductor layer 150 and less than or equal to a thickness of the LED semiconductor layer, the step structure 151 at least isolates the second doping type semiconductor layers 150 of the adjacent LED units from each other, and a step surface of the step structure 151 serves as a light-emitting region of the LED semiconductor layer.

It may be understood that the step structure 151 penetrates through the second doping type semiconductor layer 150 along a thickness direction to achieve an isolation of the second doping semiconductor layers 150; or the step structure 151 penetrates through the second doping type semiconductor layer 150 and the active layer 140 along the thickness direction, or the step structure 151 penetrates through the second doping type semiconductor layer 150, the active layer 140 and the first doping type semiconductor layer 130 along the thickness direction.

In an embodiment, a thickness of the LED semiconductor layer including the first doping type semiconductor layer 130, the active layer 140, and the second doping type semiconductor layer 150 may be between about 0.3 μm and about 5 μm. In some other embodiments, the thickness of the LED semiconductor layer including the first doping type semiconductor layer 130, the active layer 140, and the second doping type semiconductor layer 150 may be between about 0.4 μm and about 4 μm. In some alternative embodiments, the thickness of the LED semiconductor layer including the first doping type semiconductor layer 130, the active layer 140, and the second doping type semiconductor layer 150 may be between about 0.5 μm and about 3 μm.
5) Referring to FIG. 3f and FIG. 3g, forming a through hole 152 in a central region (that is, the LED step surface of each LED unit) of the second doping type semiconductor layer 150 of each LED unit by etching or the like, where the through hole 152 continuously penetrates through the second doping type semiconductor layer 150, the active layer 140, the first doping type semiconductor layer 130 and the bonding layer 160 along a thickness direction, and exposes the contact 111 located on the first substrate 110.

It should be noted that an orthographic projection region, on the first substrate 110, of the through hole 152 is located in a geometric center region of an orthographic projection region, on the first substrate 110, of each LED unit or LED step surface.

It should be noted that the through hole 152 may be formed by etching one or more times, for example, referring to FIG. 3f, a central region of each LED unit may be etched for the first time to remove the second doping type semiconductor layer 150 and the active layer 140 located in the central region. It may be understood that the etching for the first time may be performed synchronously with the step of forming the step structure 151 by etching, certainly, the etching steps for different etching structures may also be adjusted according to specific situations, and a processing sequence of the through hole 152 and the step structure 151 is not limited herein. Referring to FIG. 3g, the first doping type semiconductor layer 130 and the bonding layer 160 exposed in the central region are etched for the second time to expose the contact 111 on the first substrate 110, so as to form the through hole 152. Preferably, an area of an etching region of the first time is greater than an area of an etching region of the second time.
6) Referring to FIG. 3h, forming a passivation layer 170 on a surface of a formed device epitaxial structure unit, where the passivation layer 170 further covers a sidewall of the through hole 152; and processing a region, corresponding to the through hole 152, of the passivation layer 170 to form a first opening 171, and processing a region, corresponding to the second doping type semiconductor layer 150, of the passivation layer 170 to form a second opening 172, so that the contact 111 is exposed through the first opening 171 and the second doping type semiconductor layer 150 is exposed through the second opening 172.

It should be noted that, during specific implementation, the passivation layer 170 may be formed on the surface of the formed device epitaxial structure unit first, and then the first opening 171 and the second opening 172 are formed by etching. Certainly, the passivation layer having the first opening 171 and the second opening 172 may also be formed by a selective area epitaxial manner.

In an embodiment, a material of the passivation layer 170 may be SiO₂, Al₂O₃, SiN, other suitable materials, or the like, and the passivation layer 170 may further include polyimide, SU-8 photoresist, other photo-patternable polymers, or the like.
7) Referring to FIG. 3i, forming a transparent electrode layer 180 on the passivation layer 170 on the surface of the device epitaxial structure unit, and making the transparent electrode layer 180 electrically connect to the contact 111 on the first substrate 110 and the second doping type semiconductor layer 150 from the first opening 171 and the second opening 172 respectively, where the driving circuit on the first substrate 110 may control a voltage and a current of the second doping type semiconductor layer 150 through the transparent electrode layer 180.

In an embodiment, the transparent electrode layer 180 is electrically isolated from another structural layers except the second doping type semiconductor layer 150 through the passivation layer.

In an embodiment, the electrode layer 180 is formed on a portion of the passivation layer 170. In an embodiment, a material of the electrode layer 180 may be a conductive material such as indium tin oxide (ITO), Cr, Ti, Pt, Au, Al, Cu, Ge, or Ni.

The manufacturing method described in the embodiments of the present disclosure may further reduce physical damage of a functional micro-LED step surface or a sidewall of the LED unit, reduce damage to the quantum well structure as the light-emitting region of the LED, and improve optical and electrical properties of the functional step surface.

FIG. 2b illustrates a cross-sectional view of an illustrative micro-display LED chip structure according to another embodiment of the present disclosure.

Referring to FIG. 2b, a micro-display LED chip structure includes a first substrate 110 and an LED semiconductor layer formed on the first substrate 110. The LED semiconductor layer may be fixedly bonded to the first substrate 110 through a bonding layer 160, and the LED semiconductor layer includes a plurality of LED units 100 arranged in an array.

In an embodiment, an isolation material layer 190 is disposed between two adjacent LED units 100, and the two adjacent LED units 100 are electrically isolated by the isolation material layer 190, so that each LED unit 100 can be driven independently. The first substrate 110 includes a driving circuit, the driving circuit has a plurality of contacts 111, each contact 111 corresponds to an LED unit 100, each contact 111 is located in an orthographic projection region, on the first substrate, of the LED unit 100 corresponding to the contact 111, and the LED unit 100 is further electrically connected to the contact 111 on the first substrate 110 through an electrode layer 180.

In an embodiment, each contact 111 is located in a central region of the orthographic projection region, on the first substrate, of the LED unit 100 corresponding to the contact 111, and the central region refers to a geometric center of the orthographic projection region of the LED unit 100.

Taking one of the LED units 100 as an example, the LED semiconductor layer includes a first doping type semiconductor layer 130, an active layer 140, and a second doping type semiconductor layer 150 that are sequentially stacked on the first substrate 110. A through hole corresponding to a position of the contact 111 is provided on the LED semiconductor layer, and the through hole penetrates through the LED semiconductor layer.

In an embodiment, the through hole may be disposed in a central region of the LED unit 100, and penetrates through the first doping type semiconductor layer 130, the active layer 140, the second doping type semiconductor layer 150, and the bonding layer 160 along a thickness direction.

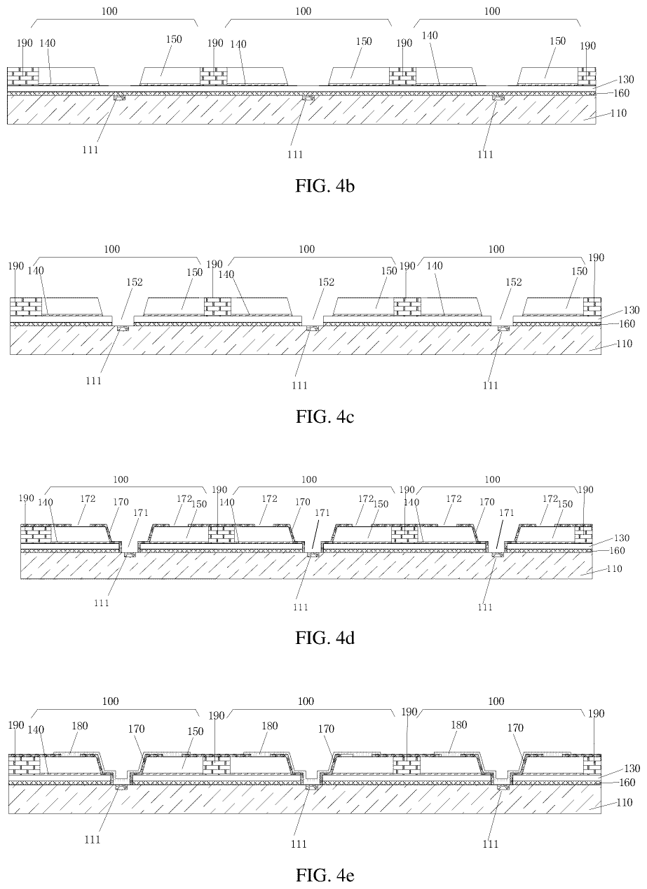

In an embodiment, a passivation layer 170 is formed on the second doping type semiconductor layer 150, an exposed portion of the first doping type semiconductor layer 130 and an exposed portion of the active layer 140, and the passivation layer 170 may be configured to protect and isolate the LED unit 100. Referring to FIG. 4d, a region, corresponding to the through hole exposing the contact 111, of the passivation layer 170 is provided with a first opening 171, and a region, corresponding to the second doping type semiconductor layer 150, of the passivation layer 170 is provided with a second opening 172. The electrode layer 180 is formed on a portion of the passivation layer 170, the electrode layer 180 is electrically connected to the contact 111 through the first opening 171 on the passivation layer 170 and the through hole, and the electrode layer 180 is electrically connected to the second doping type semiconductor layer 150 through the second opening 172 on the passivation layer 170.

In an embodiment, the first opening 171 is disposed in a central region of each LED unit 100 as much as possible, and a shape of the first opening 171 may be circular, square or the like. Of course, the first opening 171 may have another regular or irregular pattern. The second opening 172 is disposed around the first opening 171, and a shape of the second opening 172 may be defined according to specific needs, which is not limited in this embodiment.

In an embodiment, the isolation material layer 190 is at least disposed in the second doping type semiconductor layer 150, a thickness of the isolation material layer 190 is greater than or equal to a thickness of the second doping type semiconductor layer 150, and the isolation material layer 190 at least electrically isolates second doping type semiconductor layers 150 of adjacent LED units 100.

In an embodiment, the isolation material layer 190 is not in contact with the first doping type semiconductor layer 130.

In an embodiment, the isolation material layer 190 may be formed in the second doping type semiconductor layer 150, a depth of the isolation material layer 190 is insufficient to penetrate the active layer 140, and the active layer 140, the first doping type semiconductor layer 130, and the bonding layer 160 included in each LED unit may horizontally extend to adjacent LED units. Alternatively, the isolation material layer 190 may be continuously formed in the second doping type semiconductor layer 150 and the active layer 140. Alternatively, the isolation material layer 190 may be continuously formed in the second doping type semiconductor layer 150, the active layer 140, and the first doping type semiconductor layer 130.

In an embodiment, an ion implantation depth of the isolation material layer 190 may be controlled above the active layer 140. In some embodiments, the ion implantation depth of the isolation material layer 190 may be controlled so as not to penetrate the active layer 140, and the isolation material layer 190 does not in contact with the first doping type semiconductor layer 130. It should be understood that a position, a shape, and a depth of the isolation material layer 190 shown in FIG. 2b are merely illustrative and not restrictive, a person skilled in the art may make changes according to requirements, and all these changes are within the scope of the present disclosure.

In an embodiment, the isolation material layer 190 has a physical characteristic of electrical insulation, a material of the isolation material layer 190 includes an ion implantation material, and the ion implantation material includes any one or a combination of at least two of hydrogen, helium, nitrogen, oxygen, fluorine, magnesium, silicon, and argon.

Materials and structures of the first doping type semiconductor layer 130, the active layer 140, the second doping type semiconductor layer 150, the bonding layer 160, the passivation layer 170, and the electrode layer 180 in this embodiment may be substantially same as those in above embodiments, and details are not described herein again.

FIG. 4a to FIG. 4e illustrate cross-sectional views of a plurality of intermediate structures in a process of manufacturing a micro-display LED chip structure according to some embodiments of the present disclosure. It should be noted that FIGS. 4a to 4e only show a manufacturing process after the LED semiconductor layer including the first doping type semiconductor layer 130, the active layer 140, and the second doping type semiconductor layer 150 is transferred from the second substrate 120 to the first substrate 110.

Referring to FIG. 4a to FIG. 4e, a manufacturing method for a micro-display LED chip structure is provided by an embodiment of the present disclosure, which is basically consistent with the manufacturing method provided by the above embodiments, and therefore, this embodiment only introduces differences from the above embodiments, a remaining same or similar process steps and definitions of materials and structures of each epitaxial structure layer are not described in detail herein. The manufacturing method may include the following steps.
4) Referring to FIG. 4a, forming an isolation material layer 190 in the second doping type semiconductor layer 150 by ion implantation or the like.

A thickness of the isolation material layer 190 is greater than or equal to a thickness of the second doping type semiconductor layer 150, and as a result of the ion implantation, the second doping type semiconductor layer 150 is separated into a plurality of LED step surfaces by the isolation material layer 190. Each LED step surface corresponds to an LED unit, and each LED step surface is correspondingly disposed above the contact 111 on the first substrate 110, that is, the contact 111 is located in an orthographic projection region, on the first substrate 110, of the LED step surface. Particularly preferably, the contact 111 is located in a central position of the orthographic projection region, on the first substrate 110, of the LED step surface, and the central position refers to a geometrical center of the orthographic projection region.

In this embodiment, the isolation material layer 190 may be formed by implanting any one ion or a combination of at least two ions of H, He, N, O, F, Mg, Si, and Ar into the second doping type semiconductor layer 150. In this embodiment, the isolation material layer 190 has a physical characteristic of electrical insulation, and a material of the second doping type semiconductor layer 150 in a specified region may be converted into the isolation material layer 190 by implanting ions into the specified region of the second doping type semiconductor layer 150.

In this embodiment, the isolation material layer 190 may be formed at an ion implantation power between about 10 keV and about 300 keV. In some embodiments, the isolation material layer 190 may be formed at an ion implantation power between about 15 keV and about 250 keV. In some embodiments, the isolation material layer 190 may be formed at an ion implantation power between about 20 keV and about 200 keV.

In this embodiment, a depth of the ion implantation may be controlled such that the formed isolation material layer 190 penetrates through the second doping type semiconductor layer 150 along the thickness direction. Certainly, the formed isolation material layer 190 may also penetrate through the second doping type semiconductor layer 150 along the thickness direction and extend into the active layer 140. Certainly, the formed isolation material layer 190 may also penetrate the second doping type semiconductor layer 150, the active layer 140, and the first doping type semiconductor layer 130 along the thickness direction. It should be understood that a position, a shape, and a depth of the isolation material layer 190 shown in FIG. 4a are merely illustrative and not restrictive, a person skilled in the art may make changes according to specific implementations, and all these changes are within the scope of the present disclosure.
5) Referring to FIG. 4b and FIG. 4c, forming a through hole 152 in a central region (that is, the LED step surface of each LED unit) of the second doping type semiconductor layer 150 of each LED unit by etching or the like, where the through hole 152 continuously penetrates through the second doping type semiconductor layer 150, the active layer 140, the first doping type semiconductor layer 130 and the bonding layer 160 along a thickness direction, and exposes the contact 111 located on the first substrate 110.

An orthographic projection region, on the first substrate 110, of the through hole 152 is located in a geometric center region of an orthographic projection region, on the first substrate 110, of each LED unit or LED step surface.

It should be noted that the through hole 152 may be formed by etching one or more times, for example, referring to FIG. 4b, a central region of each LED unit may be etched for the first time to remove the second doping type semiconductor layer 150 and the active layer 140 located in the central region. Referring to FIG. 4c, the first doping type semiconductor layer 130 and the bonding layer 160 exposed in the central region are etched for the second time to expose the contact 111 on the first substrate 110, so as to form the through hole 152. Preferably, an area of an etching region of the first time is greater than an area of an etching region of the second time. It may be understood that a sequence of steps of forming the through hole 152 by etching and forming the isolation material layer 190 is not specifically limited.
6) Referring to FIG. 4d, forming a passivation layer 170 on a surface of a formed device epitaxial structure unit, processing a region, corresponding to the through hole 152, of the passivation layer 170 to form a first opening 171, and processing a region, corresponding to the second doping type semiconductor layer 150, of the passivation layer 170 to form a second opening 172, so that the contact 111 is exposed through the first opening 171 and the second doping type semiconductor layer 150 is exposed through the second opening 172.
7) Referring to FIG. 4e, forming a transparent electrode layer 180 on the passivation layer 170 on the surface of the device epitaxial structure unit, and making the transparent electrode layer 180 electrically connect to the contact 111 on the first substrate 110 and the second doping type semiconductor layer 150 from the first opening 171 and the second opening 172, respectively.

The contacts on the first substrate in the micro-display LED chip structure according to the embodiments of the present disclosure are correspondingly disposed in a region directly below each LED unit, rather than disposed between the adjacent LED units, so that a distance between two adjacent LED units may be reduced, and an area of a light-emitting region of the LED unit is increased, thereby improving a light-emitting brightness of the micro-display LED chip structure.

It should be understood that the above embodiments are merely used to explain the technical concepts and characteristics of the present disclosure, which are intended to enable a person skilled in the art to understand the content of the present disclosure and implement the present disclosure, and can not limit the protection scope of the present disclosure. All equivalent changes or modifications made according to the spirit of the present disclosure shall fall within the protection scope of the present disclosure.

What is claimed is:

1. A micro-display Light-Emitting Diode (LED) chip structure, comprising:
a first substrate; and
an LED semiconductor layer disposed on the first substrate, wherein the LED semiconductor layer comprises a plurality of LED units arranged in an array, and adjacent LED units of the plurality of LED units are capable of being driven independently,
wherein the first substrate comprises a driving circuit, the driving circuit is provided with a plurality of contacts, each contact of the plurality of contacts corresponds to an LED unit in the plurality of LED units, the contact is located in an orthographic projection region, on the first substrate, of the LED unit corresponding to the contact, and the contact is electrically connected to the LED unit corresponding to the contact.

2. The micro-display LED chip structure according to claim 1, wherein the contact is located in a central region of the orthographic projection region, on the first substrate, of the LED unit corresponding to the contact.

3. The micro-display LED chip structure according to claim 1, wherein the LED semiconductor layer comprises a first doping type semiconductor layer, an active layer and a second doping type semiconductor layer which are sequentially stacked on the first substrate, a through hole corresponding to a position of the contact is provided on the LED semiconductor layer, and the through hole penetrates through the LED semiconductor layer,
wherein the micro-display LED chip structure further comprises:
a passivation layer disposed on the second doping type semiconductor layer, wherein the passivation layer further covers a sidewall of the through hole, the passivation layer is provided with a first opening and a second opening, the first opening exposes the contact, and the second opening exposes the second doping type semiconductor layer; and
an electrode layer disposed on the passivation layer and covering the first opening and the second opening, wherein the electrode layer is electrically connected to the contact through the first opening, and is electrically connected to the second doping type semiconductor layer through the second opening.

4. The micro-display LED chip structure according to claim 3, wherein the LED unit is provided with a step structure, and the adjacent LED units are electrically isolated by the step structure to enable the adjacent LED units to be driven independently.

5. The micro-display LED chip structure according to claim 4, wherein the step structure is formed on the second doping type semiconductor layer, a height of the step structure is greater than or equal to a thickness of the second doping type semiconductor layer and less than a thickness of the LED semiconductor layer, and the step structure at least electrically isolates second doping type semiconductor layers corresponding to the adjacent LED units.

6. The micro-display LED chip structure according to claim 4, wherein the step structure is formed on the second doping type semiconductor layer, a height of the step structure is equal to a thickness of the LED semiconductor layer, and the step structure electrically isolates active layers corresponding to the adjacent LED units, and electrically isolates first doping type semiconductor layers corresponding to the adjacent LED units.

7. The micro-display LED chip structure according to claim 3, wherein an isolation material layer is provided between the adjacent LED units, and the adjacent LED units are electrically isolated by the isolation material layer to enable the adjacent LED units to be driven independently.

8. The micro-display LED chip structure according to claim 7, wherein the isolation material layer is formed in the second doping type semiconductor layer, a thickness of the isolation material layer is greater than or equal to a thickness of the second doping type semiconductor layer, and the isolation material layer at least electrically isolates second doping type semiconductor layers corresponding to the adjacent LED units.

9. The micro-display LED chip structure according to claim 8, wherein a material of the isolation material layer comprises an ion implantation material, and the ion implantation material comprises any one or a combination of at least two of hydrogen, helium, nitrogen, oxygen, fluorine, magnesium, silicon, and argon.

10. The micro-display LED chip structure according to claim 3, wherein first doping type semiconductor layers corresponding to the plurality of LED units are a common first doping type semiconductor layer.

11. The micro-display LED chip structure according to claim 3, wherein one of the first doping type semiconductor layer and the second doping type semiconductor layer is a P-type semiconductor layer, and the other of the first doping type semiconductor layer and the second doping type semiconductor layer is an N-type semiconductor layer.

12. The micro-display LED chip structure according to claim 3, wherein a bonding layer is disposed between the first substrate and the first doping type semiconductor layer.

13. The micro-display LED chip structure according to claim 12, wherein the bonding layer is provided with an etched hole at a position corresponding to the contact and the first opening, and the electrode layer electrically connects the second doping type semiconductor layer to the contact through the first opening and the etched hole.

14. A manufacturing method for a micro-display LED chip structure, comprising:
forming an LED semiconductor layer on a second substrate, wherein the LED semiconductor layer comprises a second doping type semiconductor layer, an active layer and a first doping type semiconductor layer which are sequentially stacked on the second substrate;
bonding the first doping type semiconductor layer to a first substrate, and removing the second substrate to expose the second doping type semiconductor layer, wherein the first substrate comprises a driving circuit, and the driving circuit is provided with a plurality of contacts; and
processing the LED semiconductor layer to form a plurality of LED units arranged in an array and enabling adjacent LED units of the plurality of LED units to be driven independently, wherein each contact of the plurality of contacts corresponds to an LED unit in the plurality of LED units, the contact is located in an orthographic projection region, on the first substrate, of the LED unit corresponding to the contact, and the contact is electrically connected to the LED unit corresponding to the contact.

15. The manufacturing method according to claim 14, wherein the processing the LED semiconductor layer to form a plurality of LED units arranged in an array comprises:
forming a plurality of step structures on the LED semiconductor layer through an etching process, wherein the plurality of step structures divide the LED semiconductor layer into the plurality of LED units arranged in an array.

16. The manufacturing method according to claim 15, wherein the forming a plurality of step structures on the LED semiconductor layer through an etching process comprises:
removing a second doping type semiconductor layer located in a plurality of selected regions by etching, so as to form the plurality of step structures, wherein a height of each step structure of the plurality of step structures is greater than or equal to a thickness of the second doping type semiconductor layer and less than a thickness of the LED semiconductor layer, and the step structure at least isolates second doping type semiconductor layers corresponding to the adjacent LED units from each other.

17. The manufacturing method according to claim 15, wherein the forming a plurality of step structures on the LED semiconductor layer through an etching process comprises:
removing a second doping type semiconductor layer, an active layer and a first doping type semiconductor layer which are located in a plurality of selected regions by etching, so as to form the plurality of step structures, wherein a height of each step structure of the plurality of step structures is equal to a thickness of the LED semiconductor layer, and the step structure isolates second doping type semiconductor layers, active layers and first doping type semiconductor layers corresponding to the adjacent LED units from each other, respectively.

18. The manufacturing method according to claim 14, wherein the processing the LED semiconductor layer to form a plurality of LED units arranged in an array comprises:
forming an isolation material layer in the second doping type semiconductor layer by ion implantation, and controlling an implantation depth of an ion implantation material to enable a thickness of the isolation material layer to be greater than or equal to a thickness of the second doping type semiconductor layer, wherein the isolation material layer at least electrically isolates second doping type semiconductor layers corresponding to the adjacent LED units, and divides the LED semiconductor layer into the plurality of LED units arranged in an array.

19. The manufacturing method according to claim 14, wherein the processing the LED semiconductor layer to form a plurality of LED units arranged in an array and enabling adjacent LED units of the plurality of LED units to be driven independently comprises:
forming a through hole penetrating through the LED semiconductor layer at a position, corresponding to the contact, on the second doping type semiconductor layer, wherein a bottom of the through hole exposes the contact;
forming a passivation layer on the second doping type semiconductor layer, wherein the passivation layer covers a sidewall of the through hole;
forming a first opening and a second opening on the passivation layer, wherein the first opening exposes the contact, and the second opening exposes the second doping type semiconductor layer; and
forming an electrode layer on the passivation layer, wherein the electrode layer is electrically connected to the contact through the first opening, and is electrically connected to the second doping type semiconductor layer through the second opening.

20. The manufacturing method according to claim 14, wherein the bonding the first doping type semiconductor layer to a first substrate comprises:
forming a bonding layer on the first doping type semiconductor layer and/or the first substrate, and then bonding the first doping type semiconductor layer to the first substrate through the bonding layer.
